(19) United States
(12) Patent Application Publication
(10) Pub. No.: US 2026/0329323 A1
(43) Pub. Date: Oct. 22, 2026

(54) MULTI-CURRENT SOURCE CIRCUIT

(71) Applicant: STMicroelectronics International N.V., Geneva (CH)

(72) Inventors: Angela CISTO, Messina (IT); Giuseppe CALCAGNO, Messina (IT); Paolo ARIGO', Messina (IT)

(21) Appl. No.: 19/180,910

(22) Filed: Apr. 16, 2025

(51) Int. Cl. G05F 3/26; H03K 3/011

(52) U.S. Cl. CPC G05F 3/262; H03K 3/011

(57) ABSTRACT

An integrated circuit is provided that comprises first, second, and third current mirrors, a PTAT current mirror block configured to provide a PTAT current output, a CTAT current mirror block configured to provide a CTAT current output, and a ZTAT current mirror block configured to provide a ZTAT current output.

### FIELD OF THE INVENTION

Example embodiments of the present disclosure relate generally to electronic circuits and, more particularly, to multi-current source circuits.

### BACKGROUND

During a project feasibility phase, a Proportional To Absolute Temperature current (PTAT current or IPTAT), a Complementary To Absolute Temperature current (CTAT current or ICTAT) and a Zero To Absolute Temperature current (ZTAT current or IZTAT) are required to bias several circuits. IPTAT is a current that increases with temperature. ICTAT is a current that decreases with temperature. IZTAT is a current which has no (or little) variation with temperature. Several approaches have been used to obtain these currents using bipolar junction transistors (BJTs).

Applicant has identified many technical challenges and difficulties associated with generating such PTAT currents, CTAT currents, and ZTAT currents. Through applied effort, ingenuity, and innovation, Applicant has solved problems related to generating PTAT currents, CTAT currents, and ZTAT currents by developing solutions embodied in the present disclosure, which are described in detail below.

### BRIEF SUMMARY

Various embodiments described herein relate to circuits, integrated circuits, and methods for multi-current source generation.

In accordance with various embodiments of the present disclosure, an integrated circuit is provided that comprises a first current mirror comprising a first metal-oxide semiconductor (MOS) transistor and a first diode-connected MOS transistor with a first node connecting a gate of the first MOS transistor and a gate of the first diode-connected MOS transistor, a second current mirror comprising a second diode-connected MOS transistor and a second MOS transistor, with a second node connecting a gate of the second diode-connected MOS transistor and a gate of the second MOS transistor, a third current mirror comprising a first bipolar transistor and a second bipolar transistor with a third node connecting a base of the first bipolar transistor and a base of the second bipolar transistor, a first resistor, a second resistor, a PTAT current mirror block, a CTAT current mirror block, and a ZTAT current mirror block. A zero to absolute temperature (ZTAT) current flows through the first diode-connected MOS transistor. A drain of the first MOS transistor is connected to a drain of the second diode-connected MOS transistor, wherein a drain of the first diode-connected MOS transistor is connected to a drain of the second MOS transistor. A source of the second diode-connected MOS transistor is connected to a collector of the first bipolar transistor, wherein a source of the second MOS transistor is connected to the third node, wherein a proportional to absolute temperature (PTAT) current flows into the collector of the second bipolar transistor. The first resistor connects the third node to ground, such that a complementary to absolute temperature (CTAT) current flows through the first resistor. The second resistor connects the emitter of the second bipolar transistor to ground. The PTAT current mirror block is connected between a drain of the first diode-connected MOS transistor and the collector of the second bipolar transistor and is configured to provide a PTAT current output. The CTAT current mirror block is connected to the second node and is configured to provide a CTAT current output. The ZTAT current mirror block is connected to the first node and is configured to provide a ZTAT current output.

In some embodiments, the PTAT current mirror block comprises a fourth current mirror and a fifth current mirror, the fourth current mirror comprises a third diode-connected MOS transistor and a third MOS transistor with a fourth node connecting a gate of the third diode-connected MOS transistor and the third MOS transistor, a drain of the third diode-connected MOS transistor is connected to a drain of the first diode-connected MOS transistor, a source of the third diode-connected MOS transistor is connected to the collector of the second bipolar transistor, the fifth current mirror comprises a fourth diode-connected MOS transistor and a fourth MOS transistor with a fifth node connecting a gate of the fourth diode-connected MOS transistor and the fourth MOS transistor, a drain of the fourth diode-connected MOS transistor is connected to a drain of the third MOS transistor, and the PTAT current output is provided via a drain of the fourth MOS transistor.

In some embodiments, the CTAT current mirror block comprises a sixth current mirror and a seventh current mirror, the sixth current mirror comprises the second diode-connected MOS transistor and a fifth MOS transistor with the second node connecting a gate of the second diode-connected MOS transistor and the fifth MOS transistor, the seventh current mirror comprises a fifth diode-connected MOS transistor and a sixth MOS transistor with a sixth node connecting a gate of the fifth diode-connected MOS transistor and the sixth MOS transistor, a drain of the fifth diode-connected MOS transistor is connected to a drain of the fifth MOS transistor, and the PTAT current output is provided via a drain of the sixth MOS transistor.

In some embodiments, the ZTAT current mirror block comprises an eighth current mirror, the eighth current mirror comprises the first diode-connected MOS transistor and a seventh MOS transistor with the first node connecting a gate of the first diode-connected MOS transistor and the seventh MOS transistor, and the ZTAT current output is provided via a drain of the seventh MOS transistor.

In some embodiments, the first MOS transistor, the fourth MOS transistor, the sixth MOS transistor, and the seventh MOS transistor each comprise a p-channel metal-oxide semiconductor (PMOS) transistor, the first diode-connected MOS transistor, the fourth diode-connected MOS transistor, and the fifth diode-connected MOS transistor each comprise a PMOS transistor, the second MOS transistor, the third MOS transistor, and the fifth MOS transistor each comprise an n-channel metal-oxide semiconductor (NMOS) transistor, and the second diode-connected MOS transistor and the third diode-connected MOS transistor each comprise an NMOS transistor.

In some embodiments, the first current mirror has a 1:M aspect ratio, the second current mirror has a 1:K aspect ratio, the third current mirror has a 1:N aspect ratio, the fourth current mirror has a 1:H aspect ratio, the fifth current mirror has a 1:1 aspect ratio, the sixth current mirror has a 1:J aspect ratio, the seventh current mirror has a 1:1 aspect ratio, the eighth current mirror has a 1:1 aspect ratio, and the ninth current mirror has a 1:H aspect ratio.

In accordance with various embodiments of the present disclosure, a current source circuit is provided that comprises a first current mirror comprising a first metal-oxide semiconductor (MOS) transistor and a first diode-connected MOS transistor with a first node connecting a gate of the first MOS transistor and a gate of the first diode-connected MOS transistor, a second current mirror comprising a second diode-connected MOS transistor and a second MOS transistor, with a second node connecting a gate of the second diode-connected MOS transistor and a gate of the second MOS transistor, a third current mirror comprising a first bipolar transistor and a second bipolar transistor with a third node connecting a base of the first bipolar transistor and a base of the second bipolar transistor, a first resistor, a second resistor, a PTAT current mirror block, a CTAT current mirror block, and a ZTAT current mirror block. A zero to absolute temperature (ZTAT) current flows through the first diode-connected MOS transistor. A drain of the first MOS transistor is connected to a drain of the second diode-connected MOS transistor, wherein a drain of the first diode-connected MOS transistor is connected to a drain of the second MOS transistor, A source of the second diode-connected MOS transistor is connected to a collector of the first bipolar transistor, wherein a source of the second MOS transistor is connected to the third node, wherein a proportional to absolute temperature (PTAT) current flows into the collector of the second bipolar transistor. The first resistor connects the third node to ground, such that a complementary to absolute temperature (CTAT) current flows through the first resistor. The second resistor connects the emitter of the second bipolar transistor to ground. The PTAT current mirror block is connected between a drain of the first diode-connected MOS transistor and the collector of the second bipolar transistor and is configured to provide a PTAT current output. The CTAT current mirror block connected to the second node and is configured to provide a CTAT current output. The ZTAT current mirror block connected to the first node and is configured to provide a ZTAT current output.

In accordance with various embodiments of the present disclosure, a current source circuit is provided that comprises a first current mirror comprising a first metal-oxide semiconductor (MOS) transistor and a first diode-connected MOS transistor with a first node connecting a gate of the first MOS transistor and a gate of the first diode-connected MOS transistor, a second current mirror comprising a second diode-connected MOS transistor and a second MOS transistor, with a second node connecting a gate of the second diode-connected MOS transistor and a gate of the second MOS transistor, a third current mirror comprising a first bipolar transistor and a second bipolar transistor with a third node connecting a base of the first bipolar transistor and a base of the second bipolar transistor, a first resistor, a second resistor, a PTAT current mirror block, a CTAT current mirror block, and a ZTAT current mirror block. A zero to absolute temperature (ZTAT) current flows through the first diode-connected MOS transistor. A drain of the first MOS transistor is connected to a drain of the second diode-connected MOS transistor, wherein a drain of the first diode-connected MOS transistor is connected to a drain of the second MOS transistor. A source of the second diode-connected MOS transistor is connected to a collector of the first bipolar transistor, wherein a source of the second MOS transistor is connected to the third node, wherein a proportional to absolute temperature (PTAT) current flows into the collector of the second bipolar transistor. The first resistor connects the third node to ground, such that a complementary to absolute temperature (CTAT) current flows through the first resistor. The second resistor connects the emitter of the second bipolar transistor to ground. The PTAT current mirror block comprises a fourth current mirror and a fifth current mirror. The fourth current mirror comprises a third diode-connected MOS transistor and a third MOS transistor with a fourth node connecting a gate of the third diode-connected MOS transistor and the third MOS transistor. A drain of the third diode-connected MOS transistor is connected to a drain of the first diode-connected MOS transistor. A source of the third diode-connected MOS transistor is connected to the collector of the second bipolar transistor. A fifth current mirror comprises a fourth diode-connected MOS transistor and a fourth MOS transistor with a fifth node connecting a gate of the fourth diode-connected MOS transistor and the fourth MOS transistor. A drain of the fourth diode-connected MOS transistor is connected to a drain of the third MOS transistor. A PTAT current output is provided via a drain of the fourth MOS transistor. The CTAT current mirror block comprises a sixth current mirror and a seventh current mirror. The sixth current mirror comprises the second diode-connected MOS transistor and a fifth MOS transistor with the second node connecting a gate of the second diode-connected MOS transistor and the fifth MOS transistor. The seventh current mirror comprises a fifth diode-connected MOS transistor and a sixth MOS transistor with a sixth node connecting a gate of the fifth diode-connected MOS transistor and the sixth MOS transistor. A drain of the fifth diode-connected MOS transistor is connected to a drain of the fifth MOS transistor. A PTAT current output is provided via a drain of the sixth MOS transistor. The ZTAT current mirror block comprises an eighth current mirror. The eighth current mirror comprises the first diode-connected MOS transistor and a seventh MOS transistor with the first node connecting a gate of the first diode-connected MOS transistor and the seventh MOS transistor. A ZTAT current output is provided via a drain of the seventh MOS transistor.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 illustrates an example multi-current source circuit, in accordance with an example embodiment of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Embodiments of the present disclosure are directed to multi-current source circuits that are able to generate IPTAT, ICTAT, and IZTAT reference currents within the same core circuit. Embodiments of the present disclosure provide IPTAT, ICTAT, and IZTAT reference current outputs. Moreover, as compared to other approaches that have been used before, some of the BJT devices have been substituted with NMOS devices to modulate the ICTAT without base-current loss. Embodiments of the present disclosure may be used with any suitable analog circuits which require a current bias reference with different dependences with respect to temperature.

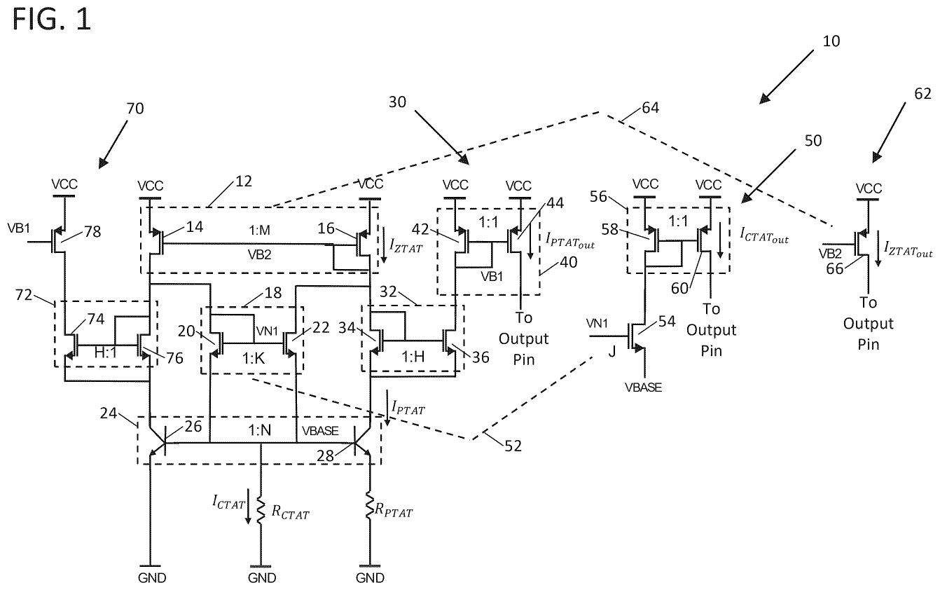

Referring now to FIG. 1, a multi-current source circuit is illustrated in accordance with an example embodiment of the present disclosure. In various embodiments, the multi-current source circuit 10 comprises a first current mirror 12, a second current mirror 18, and a third current mirror 24. A current mirror is a two-device structure which is able to mirror a certain amount of current of one device to another exploiting the ratio of the areas of the two devices. The example circuit 10 may be implemented as part of an integrated circuit (IC).

The first current mirror 12 comprises a metal-oxide semiconductor (MOS) transistor 14 and a diode-connected MOS transistor 16, with a node VB2 connecting a gate of the MOS transistor 14 and a gate of the diode-connected MOS transistor 16. As illustrated, the MOS transistor 14 comprises a p-channel metal-oxide semiconductor (PMOS) transistor, and the diode-connected MOS transistor 16 comprises a PMOS transistor. As illustrated, a ZTAT current flows through the diode-connected MOS transistor 16 of the first current mirror 12. In various embodiments, the aspect ratio of the first current mirror 12 may be expressed as 1:M.

The second current mirror 18 comprises a diode-connected MOS transistor 20 and a MOS transistor 22, with a node VN1 connecting a gate of the diode-connected MOS transistor 20 and a gate of the second MOS transistor 22. As illustrated, the diode-connected MOS transistor 20 comprises an n-channel metal-oxide semiconductor (NMOS) transistor, and the MOS transistor 22 comprises an NMOS transistor. The drain of the MOS transistor 14 of the first current mirror 12 is connected to the drain of the diode-connected MOS transistor 20 of the second current mirror 18, and the drain of the diode-connected MOS transistor 16 of the first current mirror 12 is connected to the drain of the MOS transistor 22 of the second current mirror 18. In various embodiments, the aspect ratio of the second current mirror 18 may be expressed as 1:K.

The third current mirror 24 comprises a first bipolar transistor 26 (such as a BJT) and a second bipolar transistor 28 (such as a BJT), with a node VBASE connecting a base of the first bipolar transistor 26 and a base of the second bipolar transistor 28. A source of the diode-connected MOS transistor 20 of the second current mirror 18 is connected to a base of the first bipolar transistor 26, and a source of the MOS transistor 22 of the second current mirror 18 is connected to a base of the second bipolar transistor 28. As illustrated, a PTAT current flows into the collector of the second bipolar transistor 28. In various embodiments, the aspect ratio of the third current mirror 24 may be expressed as 1:N.

The voltage across the base-emitter junction of a BJT (termed V_{BE}) is related to the collector current (Ic), the inverse saturation current, (Is), and the thermal voltage (V_{T}). The difference of the V_{BE}s of two BJTs having areas with ratio 1:N is a well-defined quantity equal to V_{T}*ln(N) if the collector currents are equal.

In various embodiments, the multi-current source circuit 10 further comprises a first resistor RCTAT connecting the VBASE node to ground and a second resistor R_{PTAT} connecting the emitter of the second bipolar transistor 28 to ground. In various embodiments, a CTAT current flows through the first resistor R_{CTAT}. In the illustrated embodiment, the emitter of the first bipolar transistor 26 is connected to ground. In various embodiments, a PTAT current flows into the collector of the second bipolar transistor 28.

In various embodiments, a multi-current source circuit such as the circuit 10 of FIG. 1 requires circuitry to output the PTAT current, the CTAT current, and the ZTAT current generated by the multi-current source circuit 10 to other circuitry external to the multi-current source circuit 10. Accordingly, multi-current source circuit 10 of various embodiments comprises a PTAT current mirror block 30 configured to provide a PTAT current output (such as via an output pin), a CTAT current mirror block 50 configured to provide a CTAT current output (such as via an output pin), and a ZTAT current mirror block 62 configured to provide a ZTAT current output (such as via an output pin).

As seen in FIG. 1, the PTAT current mirror block 30 comprises a fourth current mirror 32 and a fifth current mirror 40. The fourth current mirror 32 comprises a diode-connected MOS transistor 34 and a MOS transistor 36 with a node connecting the gates of the diode-connected MOS transistor 34 and the MOS transistor 36. The drain of the diode-connected MOS transistor 34 of the fourth current mirror 32 is connected to the drain of the diode-connected MOS transistor 16 of the first current mirror 12. A source of the diode-connected MOS transistor 34 of the fourth current mirror 32 is connected to the collector of the second bipolar transistor 28 of the third current mirror 24. In various embodiments, the aspect ratio of the fourth current mirror 32 may be expressed as 1:H.

The fifth current mirror 40 comprises a diode-connected MOS transistor 42 and a MOS transistor 44 with a node VB1 connecting the gates of the diode-connected MOS transistor 42 and the MOS transistor 44. The drain of the diode-connected MOS transistor 42 of the fifth current mirror 40 is connected to the drain of the MOS transistor 36 of the fourth current mirror 32. The PTAT current output is provided via the drain of the MOS transistor 44 of the fifth current mirror 40. In various embodiments, the aspect ratio of the fifth current mirror 40 may be expressed as 1:1.

In the illustrated embodiment, the diode-connected MOS transistor 34 and the MOS transistor 36 of the fourth current mirror 32 each comprises an NMOS transistor, and the diode-connected MOS transistor 42 and the MOS transistor 44 of the fifth current mirror 40 each comprises an PMOS transistor.

As seen in FIG. 1, the CTAT current mirror block 50 comprises a sixth current mirror 52 and a seventh current mirror 56. The sixth current mirror 52 comprises the diode-connected MOS transistor 20 of the second current mirror 18 and a MOS transistor 54. The gate of the MOS transistor 54 is connected to node VN1 to connect with the gate of the diode-connected MOS transistor 20 of the second current mirror 18. In various embodiments, the aspect ratio of the sixth current mirror 52 may be expressed as 1:J.

The seventh current mirror 56 comprises a diode-connected MOS transistor 58 and a MOS transistor 60 with a node connecting the gates of the diode-connected MOS transistor 58 and the MOS transistor 60. The drain of the diode-connected MOS transistor 58 of the seventh current mirror 56 is connected to the drain of the MOS transistor 54 of the sixth current mirror 52. The PTAT current output is provided via the drain of the MOS transistor 60 of the seventh current mirror 56. In various embodiments, the aspect ratio of the seventh current mirror 56 may be expressed as 1:1.

In the illustrated embodiment, the MOS transistor 54 of the sixth current mirror 52 comprises an NMOS transistor, and the diode-connected MOS transistor 58 and the MOS transistor 60 of the seventh current mirror 56 each comprises an PMOS transistor.

As seen in FIG. 1, the ZTAT current mirror block 62 comprises an eighth current mirror 64. The eighth current mirror 64 comprises the diode-connected MOS transistor 16 of the first current mirror 12 and a MOS transistor 66. The gate of the MOS transistor 66 is connected to node VB2 to connect with the gate of the diode-connected MOS transistor 16 of the first current mirror 12. The ZTAT current output is provided via the drain of the MOS transistor 66 of the eighth current mirror 64. In various embodiments, the aspect ratio of the eighth current mirror 64 may be expressed as 1:1. In the illustrated embodiment, the MOS transistor 66 of the eighth current mirror 64 comprises a PMOS transistor.

In various embodiments, the multi-current source circuit 10 further comprises block 70 comprising a ninth current mirror 72 and a MOS transistor 78 to make the structure symmetrical. The ninth current mirror 72 comprises a MOS transistor 74 and a diode-connected MOS transistor 76 with a node connecting the gates of the MOS transistor 74 and the diode-connected MOS transistor 76. The drain of the MOS transistor 76 is connected to the drain of the MOS transistor 14 of the first current mirror 12 and the source of the MOS transistors 74 and 76 is connected to the collector of the first bipolar transistor 26 of the third current mirror 24. The drain of the diode-connected MOS transistor 78 is connected to the drain of the MOS transistor 74 of the ninth current mirror 72. In various embodiments, the aspect ratio of the ninth current mirror 72 may be expressed as H:1.

In the illustrated embodiment, the MOS transistor 74 and the diode-connected MOS transistor 76 of the ninth current mirror 72 each comprises an NMOS transistor, and the MOS transistor 78 comprises an PMOS transistor.

In various embodiments, the variables K, H, and J (and therefore the aspect ratios of the second current mirror 18, the fourth current mirror 32, and the sixth current mirror 52) can be selected to obtain the desired ZTAT current, thereby providing better “tuneability” and increased degrees of freedom as compared to other approaches that have been used before.

In various embodiments, the multi-current source circuit can be simplified by fixing M=1 and K=1, such that the aspect ratio of the first current mirror 12 is 1:1 and the aspect ratio of the second current mirror 18 is 1:1.

The following formulas illustrate one example method of selecting parameters, such as current mirror ratios, for example embodiments of multi-current source circuits.

Fixing R_{PTAT} and R_{CTAT} to set I_{PTAT} and I_{CTAT} currents, K and H must be calculated to set the desired I_{ZTAT} value and to achieve the optimum TC for the I_{ZTAT} at the chosen temperature. J is chosen to obtain the desired value of I_{CTAT} at the output. This is demonstrated in the following formulas:

$${I}_{ZTAT} = F \cdot {I}_{PTAT} + P \cdot {I}_{CTAT} = \frac{1}{1 + H} \frac{{V}_{T} ln ( N )}{{R}_{PTAT}} + \frac{K}{1 + K + J} \frac{{V}_{BE}}{{R}_{CTAT}}$$

$${I}_{{PTAT}_{out}} = \frac{1}{H + 1} {I}_{PTAT}$$

$$\{ \begin{matrix}{I}_{{CTAT}_{1}} + {I}_{{CTAT}_{K}} = {I}_{CTAT} * \\ {I}_{{CTAT}_{K}} = K {I}_{{CTAT}_{1}}\end{matrix} \to {I}_{{CTAT}_{1}} = \frac{{I}_{CTAT}}{K + 1 + J} ; {I}_{{CTAT}_{K}} = \frac{K}{K + 1 + J} {I}_{CTAT}$$

$$\{ \begin{matrix}{I}_{{PTAT}_{1 R}} + {I}_{{PTAT}_{HR}} = {I}_{C 2} \\ {I}_{{PTAT}_{HR}} = {I}_{{PTAT}_{1 R}}\end{matrix} \to {I}_{{PTAT}_{1 R}} = \frac{{I}_{C 2}}{H + 1} ; {I}_{{PTAT}_{HR}} = \frac{H}{H + 1} {I}_{C 2}$$

$$( The same holds for the left part with {I}_{C 1} )$$

$$\text{(*} Neglecting bipolars base currents )$$

M must be chosen to guarantee I_{C1}=I_{C2}. This is demonstrated in the following formulas:

$$\{ \begin{matrix}{I}_{{ZTAT}_{2}} = \frac{{I}_{C 2}}{H + 1} + \frac{K}{K + 1 + J} {I}_{CTAT} \\ M {I}_{{ZTAT}_{2}} = {I}_{{ZTAT}_{1}} = \frac{{I}_{C 1}}{H + 1} + \frac{K}{K + 1 + J} {I}_{CTAT}\end{matrix} {\to }^{{I}_{C 1} = {I}_{C 2}} M = 1 - \frac{{I}_{CTAT}}{{I}_{{ZTAT}_{2}}} ( \frac{K - 1}{K + 1 + J} )$$

$$Where {I}_{CTAT} = \frac{{V}_{BE}}{{R}_{CTAT}} and {I}_{{ZTAT}_{2}} = \frac{{V}_{T} ln ( N )}{{R}_{PTAT} ( H + 1 )} + \frac{K}{K + 1 + J} \frac{{V}_{BE}}{{R}_{CTAT}}$$

The same equations for the basic solution are valid to find F and P, as follows:

$$\{ \begin{matrix}{I}_{ZTAT , Target} {\vert}_{T = {T}_{0}} = F \cdot \frac{{V}_{T} ln ( N )}{{R}_{PTAT}} {\vert}_{T = {T}_{0}} + P \cdot \frac{{V}_{BE}}{{R}_{CTAT}} {\vert}_{T = {T}_{0}} \\ \frac{{dI}_{ZTAT}}{dT} {\vert}_{T = {T}_{0}} = 0\end{matrix}$$

$$Where :$$

$$F = \frac{1}{1 + H} \to H = \frac{1 - F}{F} \to [ 0 < F \leq 1 ]$$

$$P = \frac{K}{K + 1 + J} \to K = \frac{P ( 1 + J )}{1 - P} \to [ P < 1 ]$$

$$M = 1 - \frac{{I}_{CTAT}}{{I}_{{ZTAT}_{2}}} ( \frac{K - 1}{K + 1 + J} )$$

The proposed solution can be simplified fixing K=1 and M=1, as follows:

$${I}_{ZTAT} = F \cdot {I}_{PTAT} + \frac{1}{2 + J} \cdot {I}_{CTAT} = \frac{1}{1 + H} \cdot \frac{{V}_{T} ln ( N )}{{R}_{PTAT}} + \frac{1}{2 + J} \cdot \frac{{V}_{BE}}{{R}_{CTAT}}$$

Fixing R_{PTAT}_{ₒ} and J, then R_{CTAT}_{ₒ} and F (so H) values must be calculated to satisfy the equations:

$$\{ \begin{matrix}{I}_{ZTAT , Target} {\vert}_{T = {T}_{0}} = F \cdot \frac{{V}_{T} ln ( N )}{{R}_{{PTAT}_{0}} G} {\vert}_{T = {T}_{0}} + \frac{1}{2 + J} \cdot \frac{{V}_{BE}}{{R}_{{CTAT}_{0}} G} {\vert}_{T = {T}_{0}} \\ F \cdot ln ( N ) ( \frac{{k}_{g}}{q} \frac{1}{{R}_{{PTAT}_{0}} G {\vert}_{T = {T}_{0}}} - {V}_{T} {\vert}_{T = {T}_{0}} \frac{L}{{R}_{{PTAT}_{0}} {G}^{2}} {\vert}_{T = {T}_{0}} ) + \frac{1}{2 + J} \cdot ( \frac{1}{{R}_{{CTAT}_{0}} G {\vert}_{T = {T}_{0}}} \frac{{dV}_{BE}}{dT} {\vert}_{T = {T}_{0}} - {V}_{BE} {\vert}_{T = {T}_{0}} \frac{L}{{R}_{{CTAT}_{0}} G {{\vert}_{T = {T}_{0}}}^{2}} {\vert}_{T = {T}_{0}} ) = 0\end{matrix}$$

$$Where :$$

$$F = \frac{1}{1 + H} \to H = \frac{1 - F}{F} \to [ 0 < F \leq 1 ]$$

Embodiments of the present disclosure enable the generation of I_{PTAT}, I_{CTAT}, and I_{ZTAT} reference currents within the same core circuit and using only N+1 bipolar transistors (as compared to N+3 in some approaches that have been used). Fewer bipolar transistors provides better performance and takes up less space. Using NMOS transistors in the second current mirror 18 removes the need for base current recovery and removes temperature variability of the circuit.

While FIG. 1 illustrates an example multi-current source circuit 10, it is noted that the scope of the present disclosure is not limited to the example circuit shown in FIG. 1. In some embodiments, an example multi-current source circuit may comprise one or more additional or alternative components.

Although the components are described with respect to functional limitations, it should be understood that the particular implementations necessarily include the use of particular hardware. It should also be understood that certain of the components described herein may include similar or common hardware. For example, two sets of circuitries may both leverage use of the same processor, network interface, storage medium, or the like to perform their associated functions, such that duplicate hardware is not required for each set of circuitries.

The use of the term “circuitry” as used herein with respect to components of the apparatus should therefore be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, storage media, network interfaces, input/output devices, and the like.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of multi-current source circuit for which use with, for example but not limited to, any suitable analog circuits which require a current bias reference with different dependences with respect to temperature.

Within the appended claims, unless the specific term “means for” or “step for” is used within a given claim, it is not intended that the claim be interpreted under 35 U.S.C. 112, paragraph 6.

1. An integrated circuit comprising:
a first current mirror comprising a first metal-oxide semiconductor (MOS) transistor and a first diode-connected MOS transistor with a first node connecting a gate of the first MOS transistor and a gate of the first diode-connected MOS transistor, wherein a zero to absolute temperature (ZTAT) current flows through the first diode-connected MOS transistor;
a second current mirror comprising a second diode-connected MOS transistor and a second MOS transistor, with a second node connecting a gate of the second diode-connected MOS transistor and a gate of the second MOS transistor, wherein a drain of the first MOS transistor is connected to a drain of the second diode-connected MOS transistor, wherein a drain of the first diode-connected MOS transistor is connected to a drain of the second MOS transistor;
a third current mirror comprising a first bipolar transistor and a second bipolar transistor with a third node connecting a base of the first bipolar transistor and a base of the second bipolar transistor, wherein a source of the second diode-connected MOS transistor is connected to a collector of the first bipolar transistor, wherein a source of the second MOS transistor is connected to the third node, wherein a proportional to absolute temperature (PTAT) current flows into the collector of the second bipolar transistor;
a first resistor connecting the third node to ground, wherein a complementary to absolute temperature (CTAT) current flows through the first resistor;
a second resistor connecting an emitter of the second bipolar transistor to ground;
a PTAT current mirror block connected between a drain of the first diode-connected MOS transistor and the collector of the second bipolar transistor, the PTAT current mirror block configured to provide a PTAT current output;
a CTAT current mirror block connected to the second node, the CTAT current mirror block configured to provide a CTAT current output; and
a ZTAT current mirror block connected to the first node, the ZTAT current mirror block configured to provide a ZTAT current output.

2. The integrated circuit of claim 1, wherein the PTAT current mirror block comprises a fourth current mirror and a fifth current mirror;
wherein the fourth current mirror comprises a third diode-connected MOS transistor and a third MOS transistor with a fourth node connecting a gate of the third diode-connected MOS transistor and the third MOS transistor;
wherein a drain of the third diode-connected MOS transistor is connected to a drain of the first diode-connected MOS transistor;
wherein a source of the third diode-connected MOS transistor is connected to the collector of the second bipolar transistor;
wherein the fifth current mirror comprises a fourth diode-connected MOS transistor and a fourth MOS transistor with a fifth node connecting a gate of the fourth diode-connected MOS transistor and the fourth MOS transistor;
wherein a drain of the fourth diode-connected MOS transistor is connected to a drain of the third MOS transistor; and
wherein the PTAT current output is provided via a drain of the fourth MOS transistor.

3. The integrated circuit of claim 2, wherein the CTAT current mirror block comprises a sixth current mirror and a seventh current mirror;
wherein the sixth current mirror comprises the second diode-connected MOS transistor and a fifth MOS transistor with the second node connecting a gate of the second diode-connected MOS transistor and the fifth MOS transistor;
wherein the seventh current mirror comprises a fifth diode-connected MOS transistor and a sixth MOS transistor with a sixth node connecting a gate of the fifth diode-connected MOS transistor and the sixth MOS transistor;
wherein a drain of the fifth diode-connected MOS transistor is connected to a drain of the fifth MOS transistor; and
wherein the PTAT current output is provided via a drain of the sixth MOS transistor.

4. The integrated circuit of claim 3, wherein the ZTAT current mirror block comprises an eighth current mirror;
wherein the eighth current mirror comprises the first diode-connected MOS transistor and a seventh MOS transistor with the first node connecting a gate of the first diode-connected MOS transistor and the seventh MOS transistor; and
wherein the ZTAT current output is provided via a drain of the seventh MOS transistor.

5. The integrated circuit of claim 4, wherein the first MOS transistor, the fourth MOS transistor, the sixth MOS transistor, and the seventh MOS transistor each comprise a p-channel metal-oxide semiconductor (PMOS) transistor;
wherein the first diode-connected MOS transistor, the fourth diode-connected MOS transistor, and the fifth diode-connected MOS transistor each comprise a PMOS transistor;
wherein the second MOS transistor, the third MOS transistor, and the fifth MOS transistor each comprise an n-channel metal-oxide semiconductor (NMOS) transistor; and
wherein the second diode-connected MOS transistor and the third diode-connected MOS transistor each comprise an NMOS transistor.

6. The integrated circuit of claim 4, wherein the first current mirror has a 1:M aspect ratio;
wherein the second current mirror has a 1:K aspect ratio;
wherein the third current mirror has a 1:N aspect ratio;
wherein the fourth current mirror has a 1:H aspect ratio;
wherein the fifth current mirror has a 1:1 aspect ratio;
wherein the sixth current mirror has a 1:J aspect ratio;
wherein the seventh current mirror has a 1:1 aspect ratio; and
wherein the eighth current mirror has a 1:1 aspect ratio.

7. A current source circuit comprising:
a first current mirror comprising a first metal-oxide semiconductor (MOS) transistor and a first diode-connected MOS transistor with a first node connecting a gate of the first MOS transistor and a gate of the first diode-connected MOS transistor, wherein a zero to absolute temperature (ZTAT) current flows through the first diode-connected MOS transistor;
a second current mirror comprising a second diode-connected MOS transistor and a second MOS transistor, with a second node connecting a gate of the second diode-connected MOS transistor and a gate of the second MOS transistor, wherein a drain of the first MOS transistor is connected to a drain of the second diode-connected MOS transistor, wherein a drain of the first diode-connected MOS transistor is connected to a drain of the second MOS transistor;
a third current mirror comprising a first bipolar transistor and a second bipolar transistor with a third node connecting a base of the first bipolar transistor and a base of the second bipolar transistor, wherein a source of the second diode-connected MOS transistor is connected to a collector of the first bipolar transistor, wherein a source of the second MOS transistor is connected to the third node, wherein a proportional to absolute temperature (PTAT) current flows into the collector of the second bipolar transistor;
a first resistor connecting the third node to ground, wherein a complementary to absolute temperature (CTAT) current flows through the first resistor;
a second resistor connecting an emitter of the second bipolar transistor to ground;
a PTAT current mirror block connected between a drain of the first diode-connected MOS transistor and the collector of the second bipolar transistor, the PTAT current mirror block configured to provide a PTAT current output;
a CTAT current mirror block connected to the second node, the CTAT current mirror block configured to provide a CTAT current output; and
a ZTAT current mirror block connected to the first node, the ZTAT current mirror block configured to provide a ZTAT current output.

8. The current source circuit of claim 7, wherein the PTAT current mirror block comprises a fourth current mirror and a fifth current mirror;
wherein the fourth current mirror comprises a third diode-connected MOS transistor and a third MOS transistor with a fourth node connecting a gate of the third diode-connected MOS transistor and the third MOS transistor;
wherein a drain of the third diode-connected MOS transistor is connected to a drain of the first diode-connected MOS transistor;
wherein a source of the third diode-connected MOS transistor is connected to the collector of the second bipolar transistor;
wherein the fifth current mirror comprises a fourth diode-connected MOS transistor and a fourth MOS transistor with a fifth node connecting a gate of the fourth diode-connected MOS transistor and the fourth MOS transistor;
wherein a drain of the fourth diode-connected MOS transistor is connected to a drain of the third MOS transistor; and
wherein the PTAT current output is provided via a drain of the fourth MOS transistor.

9. The current source circuit of claim 8, wherein the CTAT current mirror block comprises a sixth current mirror and a seventh current mirror;
wherein the sixth current mirror comprises the second diode-connected MOS transistor and a fifth MOS transistor with the second node connecting a gate of the second diode-connected MOS transistor and the fifth MOS transistor;
wherein the seventh current mirror comprises a fifth diode-connected MOS transistor and a sixth MOS transistor with a sixth node connecting a gate of the fifth diode-connected MOS transistor and the sixth MOS transistor;
wherein a drain of the fifth diode-connected MOS transistor is connected to a drain of the fifth MOS transistor; and
wherein the PTAT current output is provided via a drain of the sixth MOS transistor.

10. The current source circuit of claim 9, wherein the ZTAT current mirror block comprises an eighth current mirror;
wherein the eighth current mirror comprises the first diode-connected MOS transistor and a seventh MOS transistor with the first node connecting a gate of the first diode-connected MOS transistor and the seventh MOS transistor; and
wherein the ZTAT current output is provided via a drain of the seventh MOS transistor.

11. The current source circuit of claim 10, wherein the first MOS transistor, the fourth MOS transistor, the sixth MOS transistor, and the seventh MOS transistor each comprise a p-channel metal-oxide semiconductor (PMOS) transistor;
wherein the first diode-connected MOS transistor, the fourth diode-connected MOS transistor, and the fifth diode-connected MOS transistor each comprise a PMOS transistor;
wherein the second MOS transistor, the third MOS transistor, and the fifth MOS transistor each comprise an n-channel metal-oxide semiconductor (NMOS) transistor; and
wherein the second diode-connected MOS transistor and the third diode-connected MOS transistor each comprise an NMOS transistor.

12. The current source circuit of claim 10, wherein the first current mirror has a 1:M aspect ratio;
wherein the second current mirror has a 1:K aspect ratio;
wherein the third current mirror has a 1:N aspect ratio;
wherein the fourth current mirror has a 1:H aspect ratio;
wherein the fifth current mirror has a 1:1 aspect ratio;
wherein the sixth current mirror has a 1:J aspect ratio;
wherein the seventh current mirror has a 1:1 aspect ratio; and
wherein the eighth current mirror has a 1:1 aspect ratio.

13. A current source circuit comprising:
a first current mirror comprising a first metal-oxide semiconductor (MOS) transistor and a first diode-connected MOS transistor with a first node connecting a gate of the first MOS transistor and a gate of the first diode-connected MOS transistor, wherein a zero to absolute temperature (ZTAT) current flows through the first diode-connected MOS transistor;
a second current mirror comprising a second diode-connected MOS transistor and a second MOS transistor, with a second node connecting a gate of the second diode-connected MOS transistor and a gate of the second MOS transistor, wherein a drain of the first MOS transistor is connected to a drain of the second diode-connected MOS transistor, wherein a drain of the first diode-connected MOS transistor is connected to a drain of the second MOS transistor;
a third current mirror comprising a first bipolar transistor and a second bipolar transistor with a third node connecting a base of the first bipolar transistor and a base of the second bipolar transistor, wherein a source of the second diode-connected MOS transistor is connected to a collector of the first bipolar transistor, wherein a source of the second MOS transistor is connected to the third node, wherein a proportional to absolute temperature (PTAT) current flows into the collector of the second bipolar transistor;
a first resistor connecting the third node to ground, wherein a complementary to absolute temperature (CTAT) current flows through the first resistor;
a second resistor connecting an emitter of the second bipolar transistor to ground;
a PTAT current mirror block comprising a fourth current mirror and a fifth current mirror, wherein the fourth current mirror comprises a third diode-connected MOS transistor and a third MOS transistor with a fourth node connecting a gate of the third diode-connected MOS transistor and the third MOS transistor, wherein a drain of the third diode-connected MOS transistor is connected to a drain of the first diode-connected MOS transistor, wherein a source of the third diode-connected MOS transistor is connected to the collector of the second bipolar transistor, wherein the fifth current mirror comprises a fourth diode-connected MOS transistor and a fourth MOS transistor with a fifth node connecting a gate of the fourth diode-connected MOS transistor and the fourth MOS transistor, wherein a drain of the fourth diode-connected MOS transistor is connected to a drain of the third MOS transistor, and wherein a PTAT current output is provided via a drain of the fourth MOS transistor;
a CTAT current mirror block comprising a sixth current mirror and a seventh current mirror, wherein the sixth current mirror comprises the second diode-connected MOS transistor and a fifth MOS transistor with the second node connecting a gate of the second diode-connected MOS transistor and the fifth MOS transistor, wherein the seventh current mirror comprises a fifth diode-connected MOS transistor and a sixth MOS transistor with a sixth node connecting a gate of the fifth diode-connected MOS transistor and the sixth MOS transistor, wherein a drain of the fifth diode-connected MOS transistor is connected to a drain of the fifth MOS transistor, and wherein a PTAT current output is provided via a drain of the sixth MOS transistor; and
a ZTAT current mirror block comprising an eighth current mirror, wherein the eighth current mirror comprises the first diode-connected MOS transistor and a seventh MOS transistor with the first node connecting a gate of the first diode-connected MOS transistor and the seventh MOS transistor, and wherein a ZTAT current output is provided via a drain of the seventh MOS transistor.

14. The current source circuit of claim 13, wherein the first MOS transistor, the fourth MOS transistor, the sixth MOS transistor, and the seventh MOS transistor each comprise a p-channel metal-oxide semiconductor (PMOS) transistor;
wherein the first diode-connected MOS transistor, the fourth diode-connected MOS transistor, and the fifth diode-connected MOS transistor each comprise a PMOS transistor;
wherein the second MOS transistor, the third MOS transistor, and the fifth MOS transistor each comprise an n-channel metal-oxide semiconductor (NMOS) transistor; and
wherein the second diode-connected MOS transistor and the third diode-connected MOS transistor each comprise an NMOS transistor.

15. The current source circuit of claim 13, wherein the first current mirror has a 1:M aspect ratio;
wherein the second current mirror has a 1:K aspect ratio;
wherein the third current mirror has a 1:N aspect ratio;
wherein the fourth current mirror has a 1:H aspect ratio;
wherein the fifth current mirror has a 1:1 aspect ratio;
wherein the sixth current mirror has a 1:J aspect ratio;
wherein the seventh current mirror has a 1:1 aspect ratio; and
wherein the eighth current mirror has a 1:1 aspect ratio.
